(19) United States
(12) Patent Application Publication
(10) Pub. No.: US 2025/0378859 A1
(43) Pub. Date: Dec. 11, 2025

(54) COLUMN SPIKING REDUCTION USING RNL

(71) Applicant: Micron Technology, Inc., Boise, ID (US)

(72) Inventors: Jackson Metz, Boise, ID (US); Jiyun Li, Boise, ID (US)

(21) Appl. No.: 19/062,873

(22) Filed: Feb. 25, 2025

Related U.S. Application Data
(60) Provisional application No. 63/658,183, filed on Jun. 10, 2024.

(51) Int. Cl. G11C 7/06

(52) U.S. Cl. CPC G11C 7/065

(57) ABSTRACT

Techniques are provided for mitigating (e.g., reducing or eliminating) the column spiking issue caused by an electrical coupling due to voltage changes on a SAN signal. The column spiking is mitigated by reducing dimensions of the contact pad (e.g., Metal0 pad) of the SAN signal. Additionally or alternatively, the column spiking is mitigated by using a voltage source (e.g., via the Metal0 layers) that provides voltage changes countering the voltage changes of the SAN signal to mitigate the total electrical coupling. By mitigating the column spiking, the memory device has improved performance, such as improved sense margin consistency, reduced peak offset and reduced variation of offset in sense amplifiers, and the like. In addition, the current technology and methods improves signal margin in the SAs as well as array efficiency (AE) in the memory devices.

### CROSS-REFERENCE TO RELATED APPLICATIONS

This application claims priority to U.S. Provisional Application No. 63/658,183, filed Jun. 10, 2024, which is incorporated by reference herein in its entirety.

### BACKGROUND OF THE INVENTION

### Field of the Invention

The present invention relates generally to the field of memory devices. More specifically, embodiments of the present disclosure relate to mitigating (e.g., reducing or eliminating) column spiking issues caused by electrical couplings due to voltage changes in control signals (e.g., SAN signals) in memory devices.

### Description of the Related Art

This section is intended to introduce the reader to various aspects of art that may be related to various aspects of the present invention, which are described and/or claimed below. This discussion is believed to be helpful in providing the reader with background information to facilitate a better understanding of the various aspects of the present invention. Accordingly, it should be understood that these statements are to be read in this light, and not as admissions of prior art.

Memory devices are widely used to store information related to various electronic devices such as computers, wireless communication devices, cameras, digital displays, and the like. Memory devices are frequently provided as internal memory, integrated circuits and/or external removable devices in computers or other electronic devices. There are many different types of memory, including volatile and non-volatile memory. Volatile memory, including random access memory (RAM), static random access memory (SRAM), dynamic random access memory (DRAM), and synchronous dynamic random access memory (SDRAM), among others, may require a source of applied power to maintain its data. Non-volatile memory, by contrast, may retain its stored data even when not externally powered. Non-volatile memory is available in a wide variety of technologies, including flash memory (e.g., NAND and NOR) phase change memory (PCM), ferroelectric random access memory (FeRAM), resistive random access memory (RRAM), and magnetic random access memory (MRAM), among others.

A memory device may include a number of storage elements, such as memory cells. Memory cells of a binary memory device may, for example, include a charged or discharged capacitor. A charged capacitor of a memory cell may, however, become discharged over time through leakage currents, resulting in the loss of the stored information. Certain features of volatile memory may offer performance advantages, such as faster read or write speeds, while features of non-volatile memory, such as the ability to store data without periodic refreshing, may be advantageous in other applications. Some of the memory devices include memory cells that may be accessed by turning on a transistor that couples the memory cell (e.g., the capacitor) with a wordline or a bitline/digit line. Different memory devices may use different architectures for arranging the memory cells. For example, different memory devices may arrange the memory cells in 2-dimensional or 3-dimensional rows aid columns. A memory cell may be accessed based on activating a row and a column of the memory device corresponding to the memory cell.

Sense amplifiers (SAs) may be used by a memory device during read/write operations. For example, the read circuitry of the memory device utilizes the sense amplifiers to receive low voltage (e.g., low differential) signals and amplify the small voltage differences to enable the memory device to interpret the data properly. A sense amplifier may include multiple devices (e.g., an isolation gate, a PMOS sense amplifier (PSA), an NMOS sense amplifier (NSA)) formed on an integrated circuit (IC) chip. A SAN signal may be used to enable or disable the activation of the NSAs in the SA. The SAN signal may use a first metal layer (e.g., Metal0 layer) to contact the appropriate gate in the area, and there may be electrical coupling between the SAN contact carrying the SAN signal and its adjacent digit lines running on the Metal0 layer. When the voltage of the SAN signal changes, the adjacent digit lines may be affected by the large electrical coupling between the SAN contact and the adjacent digit lines and result in a voltage offset between the bit (digit) line signal and its complement (e.g., the bit (digit) line bar signal). The high voltage offset between the digit line pair across a sense amplifier is called column spiking. High offset between the digit line pair may create variation in the sense amplifier trip point and reduce overall sense margin, which may affect the system performance. Accordingly, it is desirable to mitigate (e.g., reduce or eliminate) the column spiking.

### BRIEF DESCRIPTION OF THE DRAWINGS

Various aspects of this disclosure may better be understood upon reading the following detailed description and upon reference to the drawings in which:

FIG. 1 is a block diagram illustrating certain features of a memory device, according to an embodiment of the present disclosure;

FIG. 2 illustrates a memory bank of the memory device of FIG. 1, according to an embodiment of the present disclosure;

FIG. 3 is a block diagram of a portion of the memory bank of FIG. 2 including sense amplifiers, according to an embodiment of the present disclosure;

FIG. 4 is a circuit diagram showing a sense amplifier and a portion of a read/write (RW) gap of the sense amplifier, according to an embodiment of the present disclosure;

FIG. 5 is a timing diagram illustrating a relationship between a SAN signal and an RNL signal of the sense amplifier of FIG. 4 with respect to time during a sense time period, according to an embodiment of the present disclosure;

FIG. 6 is a schematic diagram illustrating an embodiment of a layout of a portion of the RW gap of FIG. 4 formed on a substrate using reduced contact pads for SAN signals, according to an embodiment of the present disclosure;

FIG. 7 is a schematic diagram illustrating another embodiment of a layout of a portion of the RW gap of FIG. 4 formed on a substrate using a voltage source (e.g., the RNL signal) that may provide voltage changes countering the voltage changes of the corresponding SAN signal, according to an embodiment of the present disclosure;

FIG. 8 is a diagram illustrating the voltage offset per digit line pair in a SA region, according to an embodiment of the present disclosure; and

FIG. 9 is a flow diagram of a method for fabricating the memory device of FIG. 1 to mitigate column spiking on a digit line, according to an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

A memory device may perform memory operations such as storing data (e.g., write operations) and retrieving stored data (e.g., read operations). For example, a computing system may include various system components including one or multiple memory devices. The system components may communicate data (e.g., data bits) to perform system operations. For example, the system may include one or more processing components, one or more memory devices, among other system components. In different embodiments, the computing system may be disposed on a single electronic chip or multiple electronic chips. Moreover, the computing system may be disposed on a single electronic device or multiple electronic devices positioned in proximity of or remote from each other.

The memory device may include a number of memory banks, controller circuitry, command decoder circuitry, and a clock circuit to provide the clock signal, among other memory components. In some cases, the controller circuitry (hereinafter, controller) may include the command decoder circuitry (hereinafter, command decoder). In alternative or additional cases, the command decoder may include separate circuitry disposed between the controller and the memory banks or any other viable location. The memory device may include control blocks associated with the memory banks. In some cases, the command decoder may provide the access instructions to the control blocks of the memory banks. The memory banks and/or the control blocks of the memory banks may include sense amplifiers (SAs) used for read operations of the memory device. A SAN signal may be used to enable or disable the activation of the NSAs in a SA. The SAN signal may use a Metal0 layer to contact the appropriate gate in the area, and there may be electrical coupling between the SAN contact carrying the SAN signal and its adjacent digit lines running on the Metal0 layer. When the voltage of the SAN signal changes, the adjacent digit lines may be affected by the large electrical coupling between the SAN contact and the adjacent digit lines and result in a voltage offset between the bit (digit) line signal and its complement (e.g., the bit (digit) line bar signal). This voltage offset is generally measured using Vcell Loss. A higher voltage offset corresponding to a larger Vcell Loss. The high voltage offset (e.g., Vcell Loss<(−13 mV) or >+13 mV) between the digit line pair across a sense amplifier is called column spiking. High offset between the digit line pair may create variation in the sense amplifier trip point and reduce overall sense margin, which may affect the system performance. For example, Accordingly, it is desirable to reduce or eliminate the column spiking.

The current disclosure herein is related to mitigating (e.g., reducing or eliminating) the column spiking issue caused by an electrical coupling due to voltage changes of a SAN signal. The column spiking may be mitigated by reducing dimensions of the contact pad (e.g., SAN contact on the Metal0 layer) coupled to the SAN signal. Additionally or alternatively, the column spiking may be mitigated by using a voltage source (e.g., via the Metal0 layers) that provides voltage changes countering the voltage changes of the SAN signal to mitigate the total electrical coupling. By mitigating the column spiking, the memory device may have improved performance, such as improved sense margin consistency, reduced peak offset and reduced variation of offset in sense amplifiers, and the like. In addition, the current technology and methods improves signal margin in the SAs as well as array efficiency (AE) in the memory devices.

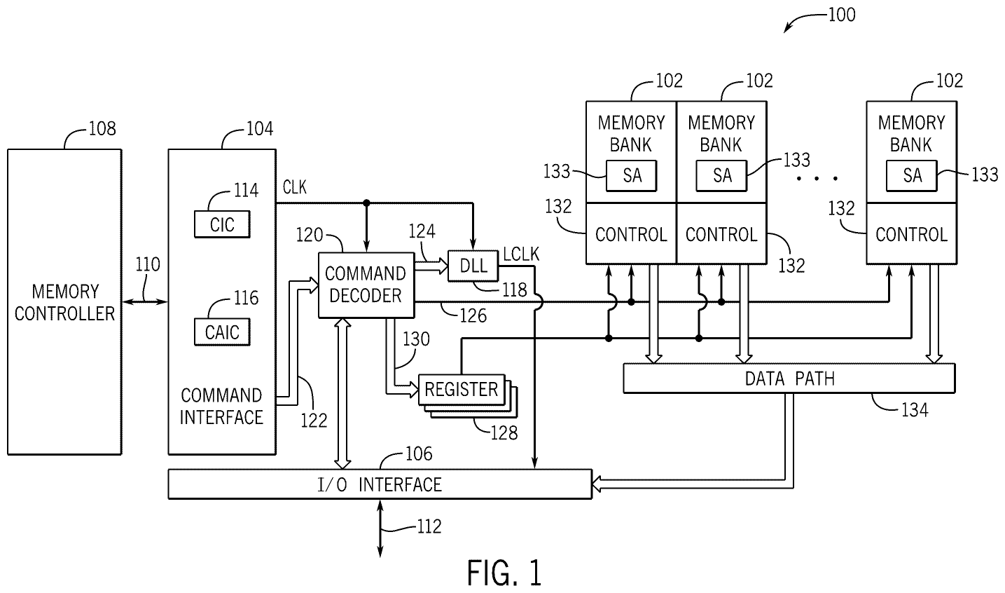

Turning now to the figures, FIG. 1 depicts a simplified block diagram illustrating certain features of a memory device 100 (e.g., a memory subsystem of an apparatus). Specifically, the block diagram of FIG. 1 depicts a functional block diagram illustrating certain functionality of the memory device 100. In accordance with one embodiment, the memory device 100 may include a random access memory (RAM) device, a ferroelectric RAM (FeRAM) device, a dynamic RAM (DRAM) device, a static RAM (SRAM) device (including a double data rate SRAM device), flash memory, and/or a 3D memory array including phase change (PC) memory and/or other chalcogenide-based memory, such as self-selecting memories (SSM). Moreover, each memory cell of such 3D memory array may include a corresponding logic storing device (e.g., a capacitor, a resistor, or the resistance of the chalcogenide material(s)).

The memory device 100 may include a number of memory banks 102 each including one or more memory arrays. Various configurations, organizations, and sizes of the memory banks 102 on the memory device 100 may be used based on an application and/or design of the memory device 100 within an electrical system. For example, in different embodiments, the memory banks 102 may include a different number of rows and/or columns of memory cells. Moreover, the memory banks 102 may each include a number of pins for communicating with other blocks of the memory device 100. For example, each memory bank 102 may receive one data bit per pin at each clock cycle. Furthermore, the memory banks 102 may be grouped into multiple memory groups (e.g., two memory groups, three memory groups).

The memory device 100 may also include a command interface 104 and an input/output (I/O) interface 106. The command interface 104 is configured to provide a number of signals received from a processor (e.g., a processor subsystem of an apparatus) or a controller, such as a memory controller 108. In different embodiments, the memory controller 108, hereinafter controller 108, may include one or more processors (e.g., memory processors), one or more programmable logic fabrics, or any other suitable processing components.

In some embodiments, a bus 110 may provide a signal path or a group of signal paths to allow bidirectional communication between the controller 108, the command interface 104 and the I/O interface 106. For example, the controller 108 may receive memory access requests from the I/O interface via the command interface 104 and the bus 110. Moreover, the controller 108 may provide the access commands and/or access instructions for performing memory operations to the command interface 104 via the bus 110.

Similarly, an external bus 112 may provide another signal path or group of signal paths to allow for bidirectional transmission of signals, such as data signals and access commands (e.g., read/write requests), between the I/O interface 106, the controller 108, a command decoder 120, and/or other components. Thus, the controller 108 may provide various signals (e.g., the access commands, the access instructions, or other signals) to different components of the memory device 100 to facilitate the transmission and receipt of data to be written to or read from the memory banks 102.

That said, the command interface 104 may receive different signals from the controller 108. For example, a reset command may be used to reset the command interface 104, status registers, state machines and the like, during power-up. Various testing signals may also be provided to the memory device 100. For example, the controller 108 may use such testing signals to test connectivity of different components of the memory device 100. In some embodiments, the command interface 104 may also provide an alert signal to the controller 108 upon detection of an error in the memory device 100. Moreover, the I/O interface 106 may additionally or alternatively be used for providing such alert signals, for example, to other system components electrically connected to the memory device 100.

The command interface 104 may also receive one or more clock signals from an external device (e.g., an external clock signal). Moreover, the command interface 104 may include a clock input circuit 114 (CIC) and a command address input circuit 116 (CAIC). The command interface 104 may use the clock input circuit 114 and the command address input circuit 116 to receive the input signals, including the access commands, to facilitate communication with the memory banks 102 and other components of the memory device 100.

Moreover, the clock input circuit 114 may receive the one or more clock signals (e.g., the external clock signal) and may generate an internal clock signal (CLK) therefrom. In some embodiments, the command interface 104 may provide the CLK to the command decoder 120 and an internal clock generator, such as a delay locked loop (DLL) 118 circuit. The DLL 118 may generate a phase controlled internal clock signal (LCLK) based on the received CLK. For example, the DLL 118 may provide the LCLK to the I/O interface 106. Subsequently, the I/O interface 106 may use the received LCLK as a clock signal for transmitting the read data using the external bus 112.

The command interface 104 may also provide the internal clock signal CLK to various other memory components. As mentioned above, the command decoder 120 may receive the internal clock signal CLK. In some cases, the command decoder 120 may also receive the access commands via a bus 122 and/or through the I/O interface 106 received via the external bus 112. For example, the command decoder 120 may receive the access commands through the I/O interface 106 transmitted by one or more external devices. In some cases, a processor may transmit the access commands.

The command decoder 120 may decode the access commands and/or the memory access requests to provide corresponding access instructions for accessing target memory cells. For instance, the command decoder 120 may provide the access instructions to one or more control blocks 132 associated with the memory banks 102 via a bus path 126. In some cases, the command decoder 120 may provide the access instructions to the control blocks 132 in coordination with the DLL 118 over a bus 124. For example, the command decoder 120 may coordinate generation of the access instructions in-line (e.g., synchronized) with the CLK and/or LCLK. In some cases, the command decoder 120 may receive the access commands using a rising edge and/or a falling edge of the external clock signal. For example, a processor may transmit the access commands using a memory command protocol, such as a single clock cycle memory command protocol, or a multi-clock cycle memory command protocol. The processor may use a specific memory command protocol based at least in part on the number of pins of the memory device 100 or the I/O interface 106, the number of rows and/or columns of the memory banks 102, and the number of memory banks 102. Subsequently, the command decoder 120 may provide the access instructions to the memory banks 102 based on receiving and decoding the access commands.

Accordingly, the command decoder 120 may provide the access instructions to the memory banks 102 using one or multiple clock cycles of the CLK via the bus path 126. The command decoder 120 may also transmit various signals to one or more registers 128 via, for example, one or more global wiring lines 130. Moreover, the memory device 100 may include other decoders, such as row decoders and column decoders, to facilitate access to the memory banks 102, as discussed below.

In some embodiments, each memory bank 102 may include a respective control block 132. In some cases, each of the control blocks 132 may also provide row decoding and column decoding capability based on receiving the access instructions. Accordingly, the control block 132 may facilitate accessing the memory cells of the respective memory banks 102. For example, the control blocks 132 may include circuitry (e.g., logic circuitry) to facilitate accessing the memory cells of the respective memory banks 102 based on receiving the access instructions. For example, each memory bank 102 and/or corresponding control block 132 may include sense amplifiers 133 for read operations of the memory cells of respective memory bank 102.

In some cases, the control blocks 132 may receive the access instructions and determine target memory banks 102 associated with the target memory cells. In specific cases, the command decoder 120 may include the control blocks 132. Moreover, the control blocks 132 may also provide timing control and data control functions to facilitate execution of different commands with respect to the respective memory banks 102.

Furthermore, the command decoder 120 may provide register commands to the one or more registers 128 to facilitate operations of one or more of the memory banks 102, the control blocks 132, and the like. For example, one of the one or more registers 128 may provide instructions to configure various modes of programmable operations and/or configurations of the memory device 100. The one or more registers 128 may be included in various memory devices to provide and/or define operations of various components of the memory device 100.

In some embodiments, the one or more registers 128 may provide configuration information to define operations of the memory device 100. For example, the one or more registers 128 may include operation instructions for DRAMs, synchronous DRAMs, FeRAMs, chalcogenide memories (e.g., SSM memory, PC memory), or other types of memories. As discussed above, the one or more registers 128 may receive various signals from the command decoder 120, or other components, via the one or more global wiring lines 130.

In some embodiments, the one or more global wiring lines 130 may include a common data path, a common address path, a common write command path, and a common read command path. The one or more global wiring lines 130 may traverse across the memory device 100, such that each of the one or more registers 128 may couple to the global wiring lines 130. The additional registers may involve additional wiring across the memory device (e.g., die), such that the registers are communicatively coupled to the corresponding memory components.

The I/O interface 106 may include a number of pins (e.g., 7 pins) to facilitate data communication with external components (e.g., the processing component, such as a processor). Particularly, the I/O interface 106 may receive the access commands via the pins. Moreover, data stored on the memory cells of the memory banks 102 may be transmitted to and/or retrieved from the memory banks 102 over a data path 134. The data path 134 may include a plurality of bi-directional data buses to one or more external devices via the I/O interface 106. For certain memory devices, such as a DDR5 SDRAM memory device, the I/O signals may be divided into upper and lower bytes; however, such segmentation is not utilized in conjunction with other memory device types.

That said, in different embodiments, the memory device 100 may include additional or alternative components. That is, the memory device 100 may include additional or alternative components such as power supply circuits (for receiving external VDD and VSS signals), read/write amplifiers (to amplify signals during read/write operations), temperature sensors (for sensing temperatures of the memory device 100), etc. Accordingly, it should be understood that the block diagram of FIG. 1 is only provided to highlight certain functional features of the memory device 100 to aid in the subsequent detailed description.

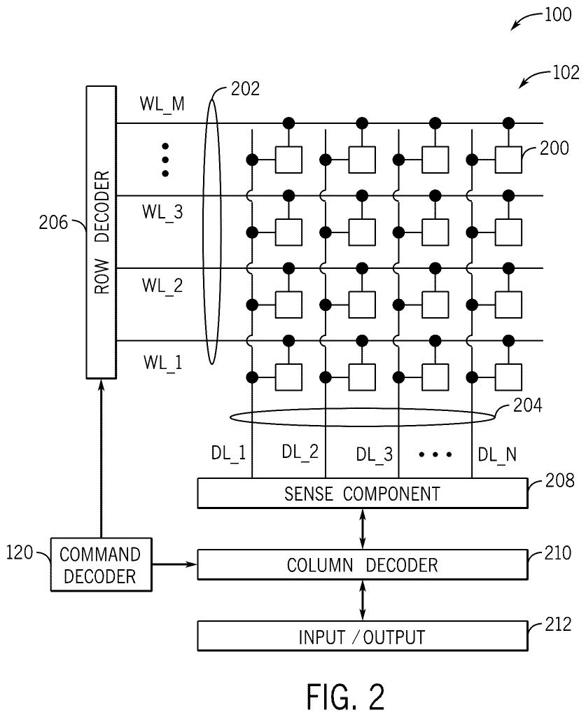

Referring now to FIG. 2, a memory bank 102 of the memory device 100 is illustrated in accordance with various examples of the present disclosure. The memory bank 102 may include a number of memory cells 200 that are programmable to store different memory states. In the depicted embodiment, the memory cells 200 may be arranged in multiple rows (e.g., 22 rows, 19 rows, etc.) and multiple columns.

Memory operations, such as reading and writing memory states, may be performed on the memory cells 200 by activating or selecting the appropriate word lines 202 and digit lines 204. Activating or selecting a word line 202 or a digit line 204 may include applying a voltage to the respective lines. The word lines 202 and the digit lines 204 may include conductive materials.

For example, word lines 202 and digit lines 204 may be made of metals (such as copper, aluminum, gold, tungsten, etc.), metal alloys, other conductive materials, or the like. In the depicted embodiment, each row of the memory cells 200 is connected to a single word line 202, and each column of the memory cells 200 is connected to a single digit line 204. Moreover, each of the memory cells 200 may be associated with a row and a column of the memory bank 102. Accordingly, each of the memory cells 200 is connected to a respective word line 202 and a respective digit line 204.

By applying a voltage to a single word line 202 and a single digit line 204, a single memory cell 200 may be activated (or accessed) at their intersection. Accessing the memory cell 200 may include performing reading or writing operation on the memory cell 200. For example, a read operation may include sensing a charge level from the memory cell 200. The intersection of a word line 202 and digit line 204 may be referred to as an address of a respective memory cell 200. Accordingly, the command decoder 120 may provide the access instructions, including the address bits, to indicate the word lines 202 and digit lines 204 corresponding to the target memory cells 200.

In some architectures, the memory state storage of the memory cell 200 (e.g., a capacitor) may be electrically isolated from the digit line by a selection component. The word line 202 may be connected to and may control the selection component. For example, the selection component may be a transistor and the word line 202 may be connected to the gate of the transistor. Activating the word line 202 may result in an electrical connection or closed circuit between the capacitor of the memory cell 200 and its corresponding digit line 204. The digit line 204 may then be activated to either read or write the memory cell 200.

Accordingly, accessing the memory cell 200 may be controlled through a respective row decoder 206 and a respective column decoder 210. As mentioned above, in different embodiments, the controller 108, the command decoder 120, and/or the control blocks 132 may include the row decoder 206 and/or the column decoder 210. In some examples, the row decoder 206 may receive a row address from the command decoder 120 and may activate the appropriate word line 202 based on the received row address.

Similarly, a column decoder 210 may receive a column address from the command decoder 120 and may activate the appropriate digit line 204. The command decoder 120 may provide the row address and the column address based on receiving and decoding the access commands and providing the access instructions. For example, the memory bank 102 may include multiple word lines 202, labeled WL_1 through WL_M, and multiple digit lines 204, labeled DL_1 through DL_N, where M and N depend on the array size. Thus, by activating a word line 202 and a digit line 204, e.g., WL_2 and DL_3, the memory cell 200 at their intersection may be accessed.

In any case, upon accessing, the memory cell 200 may be read, or sensed, by a sense component 208 (e.g., includes one or more sense amplifiers (SAs) 133) to determine the stored state of the memory cell 200. For example, after accessing the memory cell 200, a ferroelectric capacitor of the memory cell 200 may discharge a first charge (e.g., a dielectric charge) onto its corresponding digit line 204. In other examples, after accessing the memory cell 200, the ferroelectric capacitor of the memory cell 200 may discharge a second or third charge (e.g., a polarization charge) onto its corresponding digit line 204. Discharging the ferroelectric capacitor may be based on biasing, or applying a voltage, to the ferroelectric capacitor.

The discharging may induce a change in the voltage of the digit line 204, which sense component 208 may compare to a reference voltage (not shown) in order to determine the stored state of the memory cell 200. For example, if the digit line 204 has a higher voltage than the reference voltage, then sense component 208 may determine that the stored state in the memory cell 200 is related to a first predefined memory state. In some cases, the first memory state may include a state 1, or may be another value-including other logic values associated with multi-level sensing that enables storing more than two values (e.g., 3 states per cell or 1.5 bits per cell). The sense component 208 may include various transistors or amplifiers in order to detect and amplify a difference in the signals, which may be referred to as latching. The detected logic state of the memory cell 200 may then be output through column decoder 210 as output 212.

In some examples, detecting and amplifying a difference in the signals may include latching a charge that is sensed in sense component 208. One example of this charge may include latching a dielectric charge associated with the memory cell 200. As an example, the sense component 208 may sense a dielectric charge associated with the memory cell 200. The sensed dielectric charge may be latched in a latch within the sense component 208 or a separate latch that is in electronic communication with the sense component 208.

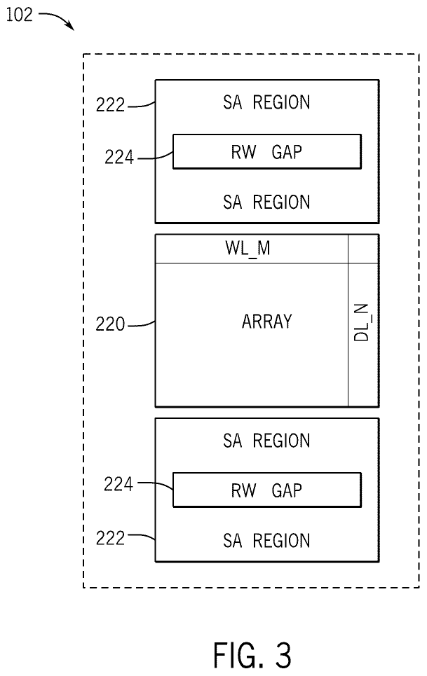

FIG. 3 is a block diagram of a portion of the memory bank 102, which may include a memory array 220 and several sense amplifier regions 222 associated with the memory array 220. Each sense amplifier (SA) region 222 may include multiple sense amplifiers (e.g. SA 133). Each sense amplifier (SA) region 222 may also include a respective read/write (RW) gap 224, which includes circuits used to selectively activate one or more of the sense amplifiers in the SA region 222.

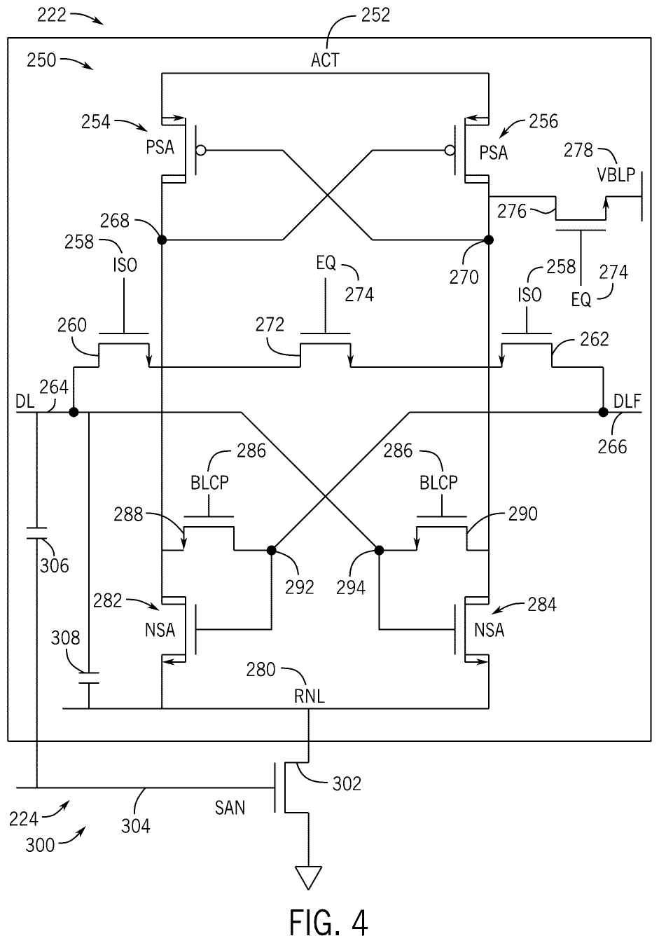

FIG. 4 is a circuit diagram showing a portion of a SA region 222 including a sense amplifier 250 that may be implemented as an embodiment of the sense amplifiers 133 of FIG. 1. Although only a single sense amplifier 250 is shown in FIG. 4, multiple sense amplifiers 133 are included in the memory device 100 that may share at least some control signals and/or supply voltages.

As illustrated, the sense amplifier 250 receives an activate signal (ACT) 252 as a local voltage. The ACT 252 activates the sense amplifier 250 by providing an operating voltage to the sense amplifier 250. In particular, the ACT 252 is coupled to respective PMOS (p-channel metal-oxide semiconductor) transistors in a PMOS sense amplifier (PSA) 254 and a PMOS sense amplifier (PSA) 256 of the sense amplifier 250, respectively. In the current disclosure, terms PSA 254 and PSA 256 are referred to herein as the respective PMOS transistor in the corresponding PSA. The sense amplifier 250 also receives an isolation signal (ISO) 258, which is used by transistors 260 and 262 to couple and decouple internal circuitry of the sense amplifier 250 from respective digit lines (DL) 264 and DLF (DL flipped)) 266. The digit line (DL) 264 may be indicative of the data in the memory cell as a “bit line true” signal (BLT) while the digit line (DLF) 266 may be opposite as a complementary “bit line bar/false” signal (BLB). The transistors 260 and 262 are coupled to the PSAs 254 and 256 at gut nodes 268 and 270, respectively. Thus, the ISO 258 controls coupling of the gut node 268 to and decoupling of the gut node 268 from the digit line (DL) 264 via the transistor 260. Similarly, the ISO 258 controls coupling of the gut node 270 to and decoupling of the gut node 270 from the digit line (DLF) 266 via the transistor 262. Gut nodes 268 and 270 are each coupled to a respective first terminal (e.g., gate) of one of the PSAs 254 and 256 and a respective second terminal (e.g., drain) of the other of the PSAs 254 and 256.

Accordingly, when a voltage difference between the DL 264 and DLF 266 is greater than a threshold voltage Vth−1 of the transistors in the PSA 254 and PSA 256, one of the PSA 254 and the PSA 256 may be turned on and the other one may be turned off. For example, when the SA 250 is activated by the ACT 252 and the transistors 260 and 262 are turned on by the ISO 258, if the voltage on the DL 264 is higher than the voltage on the DLF 266 by at least the threshold voltage Vth−1, then the voltage at the gut node 268 is higher than the voltage at the gut node 270 by at least the threshold voltage Vth−1, and the PSA 254 is turned on due to the voltage at the gut node 270, which is connected to the gate of the PSA 254, is lower than the voltage at the gut node 268, which is connected to the drain of the PSA 254, by at least the threshold voltage Vth−1. In the example above, the PSA 256 is turned off due to the voltage at the gut node 268, which is connected to the gate of the PSA 256, is higher than the voltage at the gut node 270, which is connected to the drain of the PSA 256. Similarly, when the voltage on the DLF 266 is higher than the voltage on the DL 264 by at least the threshold voltage Vth−1, the PSA 256 is turned on and the PSA 254 is turned off. When either the PSA 254 or the PSA 256 is turned on, the voltage difference between the DL 264 and DLF 266 may be amplified.

The sense amplifier 250 further includes a transistor 272, which is used to equalize the voltages of the gut nodes 268 and 270 based on an equalization signal (EQ) 274. In addition, the sense amplifier 250 includes a transistor 276 coupled to the gut node 270 so that the gut node 270 may be discharged/charged to a bit line precharge voltage (VBLP) 278 via the transistor 276 when the EQ 274 is asserted.

The sense amplifier 250 further receives an RNL (row Nsense latch) signal 280. The RNL signal 280 is coupled to respective NMOS (n-channel metal-oxide semiconductor) transistors in an NMOS sense amplifier (NSA) 282 and an NMOS sense amplifier (NSA) 284 of the SA 250, respectively. The RNL signal 280 may be a voltage signal that provides an activation voltage to activate the NSA 282 and the NSA 284 (e.g., enabled via control signals in a read/write gap for the sense amplifier 250), as described in detail below. In the current disclosure, terms NSA 282 and NSA 284 are referred to herein as the respective NMOS transistors in the corresponding NSA. The SA 250 further receives a bit line compensation enable signal (BLCP) 286, which is coupled to respective gates of a transistor 288 and a transistor 290, respectively. The transistor 288 is coupled to the DLF 266 via a sense node 292, and the transistor 290 is coupled to the DL 264 via a sense node 294. Sense nodes 292 and 294 are each coupled to a respective first terminal (e.g., gate) of one of the NSAs 282 and 284 and a respective second terminal (e.g., drain) of one of the transistors 288 and 290. A respective second terminal (e.g., drain) of the NSA 282 is coupled to the gut node 268, and a respective second terminal (e.g. drain) of the NSA 284 is coupled to the gut node 270. Thus, the BLCP 286 controls coupling of the NSA 282 to and decoupling of the NSA 282 from the DLF 266 via the transistor 288. Similarly, the BLCP 286 controls coupling of the NSA 284 to and decoupling of the NSA 284 from the DL 264 via the transistor 290.

Accordingly, when a voltage difference between the DL 264 and DLF 266 is greater than a threshold voltage Vth−2 of the transistors in the NSA 282 and NSA 284, one of the NSA 282 and the NSA 284 may be turned on and the other one may be turned off. For example, when the NSA 282 and the NSA 284 are activated by the RNL signal and the transistors 288 and 290 are turned off by the BLCP 286, if the voltage on the DL 264 is higher than the voltage on the DLF 266 by at least the threshold voltage Vth−2, then the voltage at the sense node 294 is higher than the voltage at the gut node 270 by at least the threshold voltage Vth−2, and the NSA 284 is turned on due to the voltage at the sense node 294, which is connected to the gate of the NSA 284, is higher than the voltage at the gut node 270, which is connected to the drain of the NSA 284, by at least the threshold voltage Vth−2. In the example above, the NSA 282 is turned off due to the voltage at the sense node 292, which is connected to the gate of the NSA 282, is lower than the voltage at the gut node 268, which is connected to the drain of the NSA 282. Similarly, when the voltage on the DLF 266 is higher than the voltage on the DL 264 by at least the threshold voltage Vth−2, the NSA 282 is turned on and the NSA 284 is turned off. When either the NSA 282 or the NSA 284 is turned on, the voltage difference between the DL 264 and DLF 266 may be amplified.

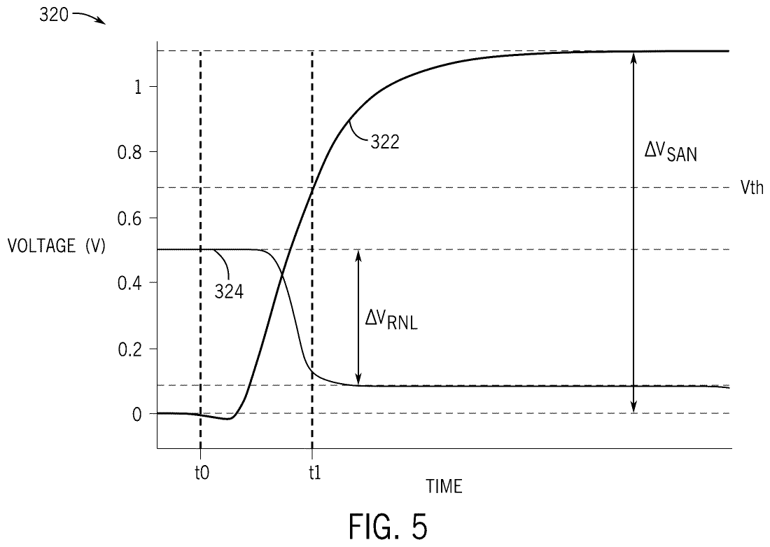

FIG. 4 also shows a portion 300 of a read/write (RW) gap 224 associated with the SA 250, which may include circuits to control timing and operation of the SA 250. For example, the RNL signal 280 may be coupled to a voltage source (e.g., ground) via a switch device, such as a transistor 302 (e.g., an NMOS transistor) in the portion 300, and when the transistor 302 is turned on, the RNL signal 280 is connected to the voltage source (e.g., ground), thereby activating the NSA 282 and the NSA 284. A SAN signal 304 may be coupled to the gate of the transistor 302 to turn on or turn off the transistor 302 to enable or disable the activation of the NSA 282 and the NSA 284. For example, when a difference between the voltage of the SAN signal 304 and the voltage source coupled to the transistor 302 is greater than a threshold voltage Vth (e.g., 0.7V) of the transistor 302, the transistor 302 is turned on and the signal RNL signal 280 is connected to the voltage source (e.g., ground), which activates the NSA 282 and the NSA 284, as illustrated in FIG. 5.

FIG. 5 is a timing diagram 320 illustrating a relationship between the SAN signal 304 and the RNL signal 280 with respect to time during a sense time period. As illustrated in FIG. 5, a curve 322 shows changes of the voltage of the SAN signal 304 with respect to time, and a curve 324 shows changes of the voltage of the RNL signal 280 with respect to time. At time t0, the sense time starts, the voltage of the SAN signal 304 increases from a low voltage state (e.g., 0 volt (V)) and the voltage of the RNL signal 286 is at a high state (e.g., 0.5 volt (V)). At time t1, when the voltage of the SAN signal 304 increases to a value greater than a threshold voltage Vth (e.g., 0.7V) of the transistor 302, the transistor 302 is turned on, the RNL signal 280 is connected to the voltage source (e.g., ground) and the voltage of the RNL signal 280 is at a low state (e.g., 0.1V). The voltage of the SAN signal 304 may continue increasing to a high state (e.g., 1.26V), while the voltage of the RNL signal 280 is at the low state (e.g., 0.1V). Therefore, the voltage change on the SAN signal 304 during the sense time may be ΔV_{SAN} (e.g., ΔV_{SAN}˜(+1.26V)), and the voltage change on the RNL signal 280 during the sense time may be ΔV_{RNL} (e.g., ΔV_{RNL}˜(−0.4V)).

Returning to FIG. 4, there may be a parasitic capacitance 306 between the SAN contact carrying the SAN signal 304 and the DL 264 in some embodiments. Parasitic capacitance may limit the operating frequency and bandwidth of electronic components and circuits (e.g., high-frequency circuits). As appreciated, the parasitic capacitance may be generated when two electrical conductors at different voltages are spatially close to each other (e.g., conductive contacts or access lines) since the electric field between them may cause electric charge to be stored on them, thereby generating the parasitic capacitance. With regard to embodiments of the present disclosure, materials may be deposited and patterned on a substrate for fabricating the various components in the memory device 100 (e.g., the SA region 222 including the RW gap 224). For example, the materials may form a structure including a p-channel transistor active area (e.g., for the PSA 254, the PSA 256), an n-channel transistor active area (e.g., for the NSA 282, the NSA 284), a Poly (polysilicon) area, a Dummy Poly area, a contact redistribution layer (or contact routing layer), a contact layer 1, a Metal0 layer, a contact layer 2, a Metal1 layer, etc. The SAN signal 304 may use the Metal0 layer to contact the appropriate gate in the area, and there may be electrical coupling between the SAN contact carrying the SAN signal 304 and its adjacent digit lines (e.g., the DL 264) running on the Metal0 layer through the RW gap 224.

When the voltage of the SAN signal 304 changes (e.g., in a range of 0-1.26V during sense time), the adjacent digit lines may be affected and result in a voltage offset between the bit (digit) line signal (e.g., the DL 264) and the bit (digit) line bar signal (e.g., the DLF 266). As previously described, the high voltage offset between the digit line pair (e.g., the DL 264 and the DLF 266) across a sense amplifier may be referred to as column spiking. As discussed above with reference to the SA 250, control of the voltage difference between the DL 264 and DLF 266 is important in the operation of the SA 250. Therefore, high offset between the digit line pair may create variation in sense amplifier trip point and reduce overall sense margin, which may affect the system performance. Accordingly, it is desirable to mitigate (e.g., reduce or eliminate) the column spiking.

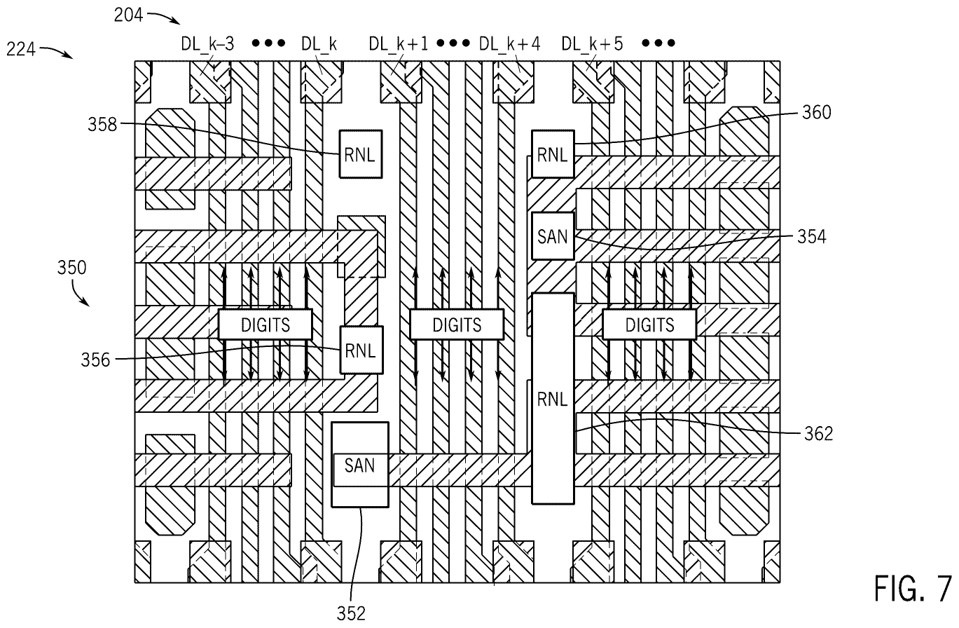

As illustrated in FIG. 5, the voltage changes on the RNL signal 280 (e.g., ΔV_{RNL}˜(−0.4V)) may counter a portion of the voltage changes on the SAN signal 304 (e.g., ΔV_{SAN}˜(+1.26V)). Therefore, a parasitic capacitance 308 between the RNL signal 280 and the DL 264 may reduce the total electrical coupling between the SAN signal 304 and the digit line DL 264. For example, when the voltage of the RNL signal 280 changes (e.g., in a range of 0.5-0.1V during sense time), the adjacent digit lines may be affected and result in an opposite voltage offset between the bit (digit) line signal (e.g., the DL 264) and the bit (digit) line bar signal (e.g., the DLF 266), which may reduce or eliminate the voltage offset caused by the SAN signal 304, as illustrated in FIG. 7. In other words, by increasing a higher parasitic capacitance 308 between the RNL signal 280 and the DL 264, the parasitic capacitance 306 created by the aggressive coupling from the SAN signal may be advantageously offset, thereby reducing column spiking.

Implementations herein are directed to techniques to mitigate (e.g., reduce or eliminate) column spiking caused by an electrical coupling due to voltage changes of the SAN signal. In some embodiments, the column spiking may be mitigated by reducing dimensions of the contact pad (e.g., SAN contact pad formed on the Metal0 layer) of the SAN signal. In some embodiments, the column spiking may be mitigated by using a voltage source (e.g., via the Metal0 layers) that may provide voltage changes countering the voltage changes of the SAN signal to mitigate the total electrical coupling.

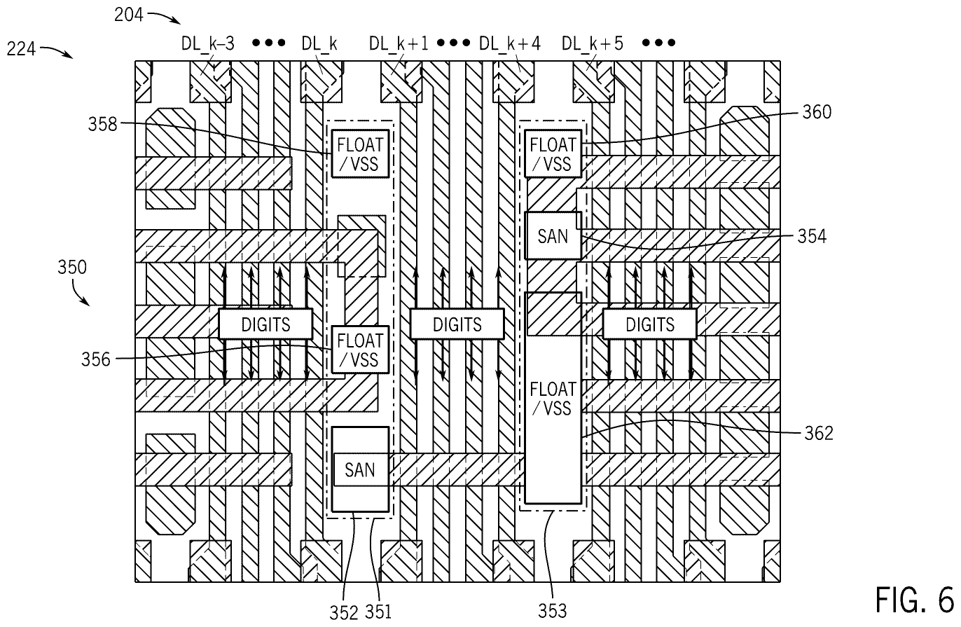

For instance, the parasitic capacitance is proportional to the coupling areas of the two signals (e.g., the SAN signal 304 and the DL 264) and inversely proportional to the distance separating the two coupling areas. Therefore, the larger the two coupling areas or the smaller the distance separating the two coupling areas, the larger the parasitic capacitance may be. Therefore, two adjacent areas may have larger parasitic capacitance due to smaller distances between them. Accordingly, reducing the coupling areas between two adjacent areas may greatly reduce the parasitic capacitance. For example, the contact pad (e.g., the SAN contact formed on the Metal0 layer) carrying the SAN signal 304 may be designed to have reduced dimensions so that the electrical couplings between the SAN signal 304 and the adjacent digit lines (e.g., the DL 264) may be reduced, as illustrated in FIG. 6.

FIG. 6 is a schematic diagram illustrating an embodiment of a layout 350 of a portion of the RW gap 224 formed on a substrate. The layout 350 may include a contact pad 351 for a SAN signal (e.g., the SAN signal 304) and a contact pad 353 for another SAN signal. Some of the digit lines 204 (e.g., DL_k−3, DL_k−2, . . . DL_k, DL_k+1, . . . DL_k+4, DL_k+5 . . . k=4, 5, 6 . . . ) may run on the Metal0 layer through the RW gap 224. The SAN signal (e.g., the SAN signal 304) may use the contact pad 351 (e.g., on the Metal0 layer) to contact the appropriate gate in the area, and there may be electrical coupling between the contact pad 351 and its adjacent digit lines (e.g., DL_k and DL_k+1) running through the RW gap 224 (e.g., on Metal0 layer). When the voltage of the SAN signal coupled to the contact pad 351 changes (e.g., in a range of 0-1.26V during sense time), the adjacent digit lines (e.g., DL_k and DL_k+1) may be affected and result in a high offset between the bit (digit) line signal (e.g., the DL 264) and the bit (digit) line bar signal (e.g., the DLF 266). To mitigate the electrical coupling between the contact pad 351 and the adjacent digit lines (e.g., DL_k and DL_k+1), the dimensions of the contact pad 351 may be adjusted or reduced (e.g., reduce the dimensions along the adjacent digit lines) to reduce the coupling area between the contact pad 351 and the adjacent digit lines. For example, the contact pad 351 may be separated into a number (e.g., 2, 3, 4 . . . ) of individual contact pads, such as a contact pad 352, a contact pad 356, and a contact pad 358. The contact pad 352 may be coupled to the SAN signal (e.g., the SAN signal 304), while the contact pad 356 and the contact pad 358 may be coupled to a voltage source (e.g., float/VSS) having a fixed voltage. Accordingly, the voltage changes of the SAN signal coupled to the contact pad 352 may have less electrical coupling with the adjacent digit lines (e.g., DL_k and DL_k+1) due to the reduced coupling area.

Similarly, the dimensions of the contact pad 353 may be adjusted or reduced (e.g., reduce the dimensions along the adjacent digit lines) to reduce the coupling area between the contact pad 353 and the adjacent digit lines (e.g., DL_k+4 and DL_k+5). For example, the contact pad 353 may be separated into a number (e.g., 2, 3, 4 . . . ) of individual contact pads (e.g., smaller Metal0 segments), such as a contact pad 354, a contact pad 360, and a contact pad 362. The contact pad 354 may be coupled to the SAN signal, while the contact pad 360 and the contact pad 362 may be coupled to a voltage source (e.g., float/VSS) having a fixed voltage. Accordingly, the voltage changes of the SAN signal coupled to the contact pad 354 may have less electrical coupling with the adjacent digit lines (e.g., DL_k+4 and DL_k+5) due to the reduced coupling area. In some embodiments, rather than forming one large contact pad (e.g., the contact pad 351, the contact pad 353), smaller contact pads may be formed on the Metal0 layer, and some of the smaller contact pads may be used to carry SAN signals (e.g., the SAN signal 304) while some of the smaller contact pads may be coupled to a voltage source (e.g., float/VSS, or a voltage source countering the voltage changes of the SAN signals, as described below). As will be appreciated by those skilled in the art, the various structures, such as those formed on the Metal0 layer (e.g., contact pads, digit lines, etc.), may be formed through any conventional fabrication techniques, involving various fabrication steps (e.g., deposition, patterning and etching). The minimum dimensions of the contact pads coupled to the SAN signals (e.g., the contact pad 352, the contact pad 354) may be determined based on the design rules of the layout of the SA region 222 (e.g., the layout of the RW gap 224), such as routing congestion, line spacing rules, etc. Accordingly, the contact pads coupled to the SAN signals may have different dimensions at different locations due to the different layouts in the different locations. For example, in some embodiments, the contact pad 352 may have larger dimensions (e.g., −150 nm) than the contact pad 354 (e.g., <100 nm).

In some embodiments, adjacent or nearby contact pads (e.g., the contact pads 356 and 358, the contact pads 360 and 362) may be coupled to a corresponding voltage source (e.g., via the Metal0 layers) that may provide voltage changes countering the voltage changes of the corresponding SAN signals (e.g., the contact pad 352, the contact pad 354) to mitigate the total electrical couplings, as illustrated in FIG. 7. FIG. 7 is a schematic diagram illustrating another embodiment of a layout 350 of a portion of the RW gap 224 using a voltage source (e.g., the RNL signal 280) that may provide voltage changes countering the voltage changes of the corresponding SAN signal (e.g., the SAN signal 304). As illustrated in FIG. 5, the voltage change on the SAN signal 304 during the sense time may be a positive value ΔV_{SAN} (e.g., ΔV_{SAN}˜(+1.26V)) and the voltage change on the RNL signal 280 during the sense time may be inversely related to the voltage change on the SAN signal 304 and have a negative value ΔV_{RNL} (e.g., ΔV_{RNL}˜(−0.4V)). Therefore, the RNL signal 280 may be used to counter the voltage change of the SAN signal 304. For example, the contact pad 356 and the contact pad 358 may be coupled to a voltage source that may provide voltage changes countering the voltage changes of the SAN signal coupled to the contact pad 352, such as the corresponding RNL signal that is enabled by the SAN signal coupled to the contact pad 352. Since the contact pad 356 and the contact pad 358 have the same adjacent digit lines (e.g., DL_k and DL_k+1) as the contact pad 352, the total electrical coupling between the contact pad 352, the contact pad 356, and the contact pad 358 with the adjacent digit lines (e.g., DL_k and DL_k+1) may be reduced.

The contact pads (e.g., the contact pad 356, the contact pad 358) connected to the RNL signal may be designed (e.g., number and/or dimensions) to obtain smaller total electrical coupling with the adjacent digit lines (e.g., DL_k and DL_k+1) based on, for example, the ΔV_{SAN} and the ΔV_{RNL} and/or the dimensions of the contact pad coupled to the SAN signal (e.g., the contact pad 352). For example, the dimensions of the contact pad 352, the contact pad 356, and the contact pad 358 may be determined based on the voltage changes of the RNL signal (e.g., ΔV_{RNL}) coupled to the contact pad 356 and the contact pad 358 and the voltage changes of the SAN signal (e.g., ΔV_{SAN}) coupled to the contact pad 352. For example, when the contact pads (e.g., the contact pads 352, 356, 358) have the same dimensions, the number of the contact pads coupled to the RNL signal to minimize the total electrical coupling may be related to the voltage changes (e.g., ΔV_{SAN}) of the SAN signal and the voltage changes (e.g., ΔV_{RNL}) of the RNL signal (e.g., 2 or 3 contact pads coupled to the RNL signal when ΔV_{SAN}˜1.26V and ΔV_{RNL}˜(−0.4V)).

Similarly, the contact pad 360 and the contact pad 362 may be coupled to a voltage source that may provide voltage changes countering the voltage changes of the SAN signal coupled to the contact pad 354, such as the corresponding RNL signal that is enabled by the SAN signal coupled to the contact pad 354, to reduce the total electrical coupling between the contact pad 354, the contact pad 362, and the contact pad 354 with the adjacent digit lines (e.g., DL_k+4 and DL_k+5). The contact pads (e.g., the contact pad 360, the contact pad 362) connected to the RNL signal may be designed (e.g., number and/or dimensions) to obtain smaller total electrical coupling with the adjacent digit lines (e.g., DL_k+4 and DL_k+5) based on, for example, the ΔV_{SAN} and the ΔV_{RNL} and/or the dimensions of the contact pad coupled to the SAN signal (e.g., the contact pad 354). For example, the dimensions of the contact pad 354, the contact pad 360, and the contact pad 362 may be determined based on the voltage changes of the RNL signal (e.g., ΔV_{RNL}) coupled to the contact pad 360 and the contact pad 362 and the voltage changes of the SAN signal (e.g., ΔV_{SAN}) coupled to the contact pad 354. For example, when the contact pads (e.g., the contact pads 354, 360, 362) have the same dimensions, the number of the contact pads coupled to the RNL signal to minimize the total electrical coupling may be related to the voltage changes (e.g., ΔV_{SAN}) of the SAN signal and the voltage changes (e.g., ΔV_{RNL}) of the RNL signal (e.g., 2 or 3 contact pads coupled to the RNL signal when ΔV_{SAN}˜1.26V and ΔV_{RNL}˜(−0.4V)).

It should be noted that, although in the illustrated embodiments of FIG. 6 and FIG. 7, the contact pads (e.g., the contact pad 356 and 358, the contact pad 360 and 362) coupled to the voltage sources (e.g., float/VSS, RNL signal) and the corresponding contact pads coupled to the SAN signals (e.g., the contact pad 352, the contact pad 354) are separated from respective contact pads (e.g., the contact pad 351, the contact pad 353), in other embodiments, any available contact pads (e.g., Metal0 pads) in the adjacent or nearby area of the contact pads (e.g., the contact pad 352, the contact pad 354) coupled to the SAN signals may be used to couple to a voltage source that may provide a fixe voltage or voltage changes countering the voltage changes of the SAN signals to reduce the total electrical coupling with the adjacent digit lines. For example, in some embodiments, rather than forming one large contact pad (e.g., the contact pad 351, the contact pad 353), smaller contact pads may be formed on the Metal0 layer, and some of the smaller contact pads may be used to carry SAN signals (e.g., the SAN signal 304) while some of the smaller contact pads may be coupled to a voltage source (e.g., float/VSS, the RNL signal 280). As will be appreciated by those skilled in the art, the various structures, such as those formed on the Metal0 layer (e.g., contact pads, digit lines, etc.), may be formed through any conventional fabrication techniques, involving various fabrication steps (e.g., deposition, patterning and etching). The minimum dimensions of the contact pads coupled to the SAN signals (e.g., the contact pad 352, the contact pad 354) may be determined based on the design rules of the layout of the SA region 222 (e.g., the layout of the RW gap 224), such as routing congestion, line spacing rules, etc. Accordingly, the contact pads coupled to the SAN signals may have different dimensions at different locations due to the different layouts in the different locations. For example, in some embodiments, the contact pad 352 may have larger dimensions (e.g., ˜150 nm) than the contact pad 354 (e.g., <100 nm).

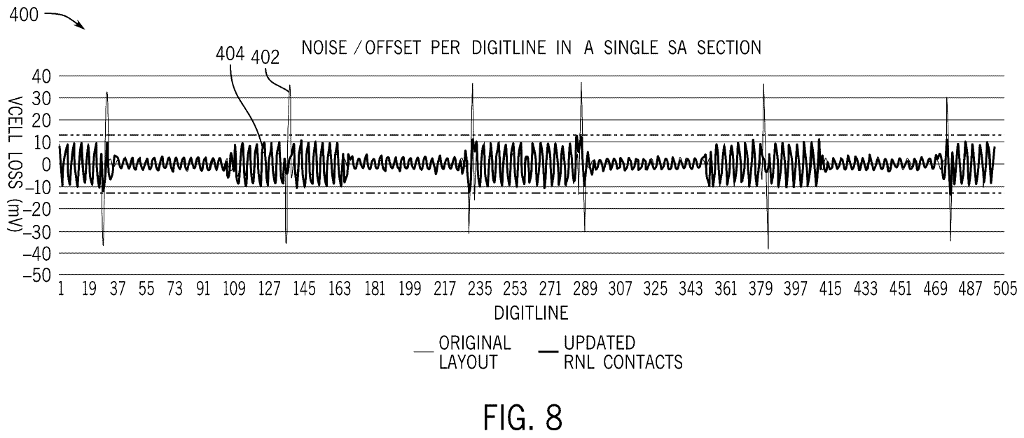

FIG. 8 is a diagram 400 illustrating the voltage offset (e.g., Vcell Loss) per digit line pair (e.g., the DL 264 and the DLF 266) in a SA region (e.g., the SA region 222). As illustrated in FIG. 8, a curve 402 shows column spiking signals when the RNL signals are not used as the voltage sources to counter the voltage changes in the SAN signals, while a curve 404 shows no column spiking signals when the RNL signals are used as the voltage sources to counter the voltage changes in the SAN signals, as described above with reference to FIG. 7. Accordingly, the memory device 100 may have improved performance (e.g., the Vcell Loss is in a range of ±13 mV) when be RNL signals are used as the voltage sources to counter the voltage changes in the SAN signals, as illustrated by the curve 404.

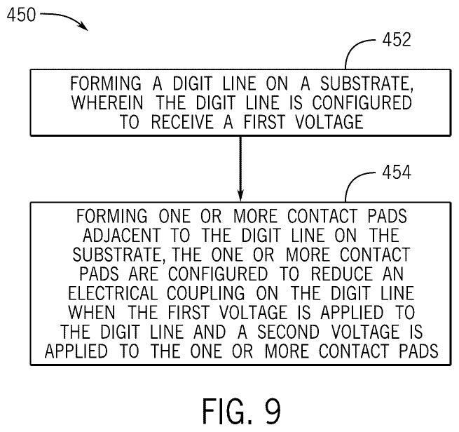

FIG. 9 is a flow diagram of a method 450 for fabricating the memory device 100 to mitigate column spiking on a digit line (e.g., the DL 264) caused by an electrical coupling due to voltage changes (e.g., ΔV_{SAN}) on a SAN signal (e.g., the SAN signal 304). The digit line may receive a first voltage, and a number and dimensions of one or more contact pads (e.g., the contact pad 356, the contact pad 358) on a substrate adjacent to the digit line may be determined to mitigate the column spiking when the one or more contact pads are coupled to a second voltage source (e.g., float/VSS, the RNL signal 280). The SAN signal is configured to enable a switch device (e.g., the switch device 302) to connect a row Nsense latch (RNL) signal (e.g., the RNL signal 280) of a sense amplifier coupled to the digit line to a third voltage source (e.g., ground) during the sense period. The SAN signal and the RNL signal may have an inverse relationship during the sense period, as illustrated in FIG. 5. For example, the voltage change on the SAN signal 304 during the sense time may be a positive value ΔV_{SAN} (e.g., ΔV_{SAN}˜(+1.26V)) and the voltage change on the RNL signal 280 during the sense time may be inversely related to the voltage change on the SAN signal 304 and have a negative value ΔV_{RNL} (e.g., ΔV_{RNL}˜(−0.4V)). The one or more contact pads (e.g., the contact pad 356, the contact pad 358) connected to the second voltage source may be designed (e.g., number and/or dimensions) to obtain smaller total electrical coupling with the adjacent digit line based on, for example, the ΔV_{SAN}, the ΔV_{RNL}, and/or the dimensions of the contact pad coupled to the SAN signal (e.g., the contact pad 352).

At block 452, the digit line may be formed on the substrate. At block 454, the one or more contact pads may be formed on the substrate based on the number and dimensions determined. In some embodiments, the one or more contact pads may be segments of a contact pad (e.g., the contact pad 351), which may be separated into several segments based on the number and dimensions determined. In some embodiments, the one or more contact pads may be formed on the Metal0 layer using the number and dimensions determined.

Accordingly, the technical effects of the present disclosure include techniques for mitigating (e.g., reducing or eliminating) column spiking caused by an electrical coupling due to voltage changes on a SAN signal. The column spiking may be mitigated by reducing dimensions of the contact pad of the SAN signal. Additionally or alternatively, the column spiking may be mitigated by using a voltage source that provides voltage changes countering the voltage changes of the SAN signal to mitigate the total electrical coupling. By mitigating the column spiking, the memory device may have improved performance, such as improved sense margin consistency, reduced peak offset and reduced variation of offset in sense amplifiers, and the like. In addition, the current technology and methods improves signal margin in the SAs as well as array efficiency (AE) in the memory devices.

In the illustrated embodiments above, the memory devices and systems are primarily described in the context of devices incorporating DRAM storage media. Memory devices configured in accordance with other embodiments of the present technology, however, may include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents, and alternatives falling within the spirit and scope of the invention as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An apparatus, comprising:
a sense amplifier of a memory device coupled to a digit line of the memory device; and
a switch device configured to connect a row Nsense latch (RNL) signal of the sense amplifier to a voltage source during a sense period of the sense amplifier when the switch device is enabled by a SAN signal, wherein the SAN signal and the RNL signal have an inverse relationship during the sense period, and wherein an electrical coupling on the digit line is generated by a first voltage change of the SAN signal during the sense period and a second voltage change of the RNL signal during the sense period is used to reduce the electrical coupling on the digit line.

2. The apparatus of claim 1, wherein a Vcell Loss of the digit line is in a range of −13 mV to 13 mV.

3. The apparatus of claim 1, wherein the first voltage change of the SAN signal is a positive value and the second voltage change of the RNL signal is a negative value.

4. The apparatus of claim 1, wherein the SAN signal is coupled to a contact pad adjacent to the digit line and the RNL signal is coupled to a number of contact pads adjacent to the digit line.

5. The apparatus of claim 4, wherein the contact pad and the number of the contact pads are separated from a same original contact pad.

6. The apparatus of claim 4, wherein the number is more than 1.

7. The apparatus of claim 4, wherein the number of the contact pads is determined based on the first voltage change and the second voltage change.

8. The apparatus of claim 4, wherein dimensions of the number of the contact pads are determined based on the first voltage change and the second voltage change.

9. A read/write (RW) circuit of a memory device, comprising:
a voltage source; and
a switch device configured to connect a row Nsense latch (RNL) signal of a sense amplifier of the memory device to the voltage source during a sense period of the sense amplifier when the switch device is enabled by a SAN signal, wherein the SAN signal and the RNL signal have an inverse relationship during the sense period, and wherein an electrical coupling on a digit line of the memory device is generated by a first voltage change of the SAN signal during the sense period and a second voltage change of the RNL signal during the sense period is used to reduce the electrical coupling on the digit line.

10. The RW circuit of claim 9, wherein a Vcell Loss of the digit line is in a range of −13 mV to 13 mV.

11. The RW circuit of claim 9, wherein the first voltage change of the SAN signal is a positive value and the second voltage change of the RNL signal is a negative value.

12. The RW circuit of claim 9, wherein the SAN signal is coupled to a contact pad adjacent to the digit line and the RNL signal is coupled to a number of contact pads adjacent to the digit line.

13. The RW circuit of claim 12, wherein the contact pad and the number of the contact pads are separated from a same original contact pad.

14. The RW circuit of claim 12, wherein the number is more than 1.

15. The RW circuit of claim 12, wherein the number of contact pads is determined based on the first voltage change and the second voltage change.

16. The RW circuit of claim 12, wherein dimensions of the number of contact pads are determined based on the first voltage change and the second voltage change.

17. A method of fabricating a memory device, comprising:
forming a digit line on a substrate, wherein the digit line is configured to receive a first voltage; and
forming one or more contact pads adjacent to the digit line on the substrate, the one or more contact pads are configured to reduce an electrical coupling on the digit line when the first voltage is applied to the digit line and a second voltage is applied to the one or more contact pads.

18. The method of claim 17, wherein the one or more contact pads comprise more than 1 contact pad.

19. The method of claim 17, wherein the electrical coupling on the digit line is generated by a voltage change of a SAN signal during a sense period of a sense amplifier coupled to the digit line, wherein the SAN signal is configured to couple a row Nsense latch (RNL) signal of the sense amplifier to a third voltage source during the sense period, and the SAN signal and the RNL signal have an inverse relationship during the sense period, and wherein the second voltage is provided by the RNL signal.

20. The method of claim 17, wherein the second voltage comprises a float/VSS voltage having a fixed value.
